(19) United States
(12) Patent Application Publication
(10) Pub. No.: US 2005/0174270 A1
(43) Pub. Date: Aug. 11, 2005

(54) Programmable variable length decoder including interface of cpu processor

(76) Inventors: Bon Tae Koo, Daejeon-city (KR); Ig Kyun Kim, Daejeon-city (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/514,733

(22) PCT Filed: May 16, 2003
(86) PCT No.: PCT/KR03/00970

(30) Foreign Application Priority Data
May 17, 2002 (KR) 1020020027333

(51) Int. Cl. H03M 7/40

(52) U.S. Cl. 341/67

(57) ABSTRACT

Provided is a programmable variable-length decoder that interfaces with an external processor. The programmable variable-length decoder includes a memory buffer, a latching unit, a multiplexing unit, a first barrel shifter, a decoding unit, and a control unit. The memory buffer stores input serial bit stream data for decoding in fixed-length data segments and outputs the stored bit stream data in response to a first control signal. The latching unit temporarily stores data output from the memory buffer and outputs the stored data in response to the first control signal. The multiplexing unit selects data from the latching unit and outputs the selected data. The first barrel shifter shifts the output of the multiplexing unit by the value of a second control signal and outputs the shifted data. The decoding unit decodes the output of the first barrel shifter and outputs decoded codewords and the bit length of the decoded codewords. The control unit adds together the bit lengths of currently decoded codewords and the bit lengths of previously decoded codewords, stores the sum, generates the first control signal and the second control signal based on the sum, and outputs the first control signal and the second control signal to the latching unit and the first barrel shifter.

### BACKGROUND OF THE INVENTION

1. Field of the Invention

The present invention relates to a decoding device for effectively decoding compressed, coded image data, and more particularly, to a programmable variable-length decoder for decoding image data which has been compressed into a variable-length code (VLC).

2. Description of the Related Art

Data compression techniques have been widely used for effectively storing and transmitting images, voice, and data. Such data compression techniques include variable-length coding. In accordance with this technique, more frequently occurring data is represented by shorter codewords and less frequently occurring data is represented by longer codewords. As a result, the average code length of a variable-length code (VLC) is shorter than the original data, thus achieving data compression.

VLC is actively used in moving picture experts group (MPEG) compression standards such as MPEG-1, MPEG-2, or MPEG-4. The compression standard MPEG-4 meets the need for high-efficiency compression and a low bit rate, important characteristics in mobile communication systems and wired/wireless multimedia applications. Therefore, a variable-length decoder must exhibit high-speed data processing, comprise a low power consumption circuit configuration, and process various header syntaxes as programs.

FIG. 1 is a block diagram of a conventional variable-length decoder. Hereinafter, the configuration and operation of the conventional variable-length decoder will be described with reference to FIG. 1.

The conventional variable-length decoder includes an external memory buffer 10, a decoding unit 30, and an interfacing unit 20. The external memory buffer 10 temporarily stores a serial bit stream of variable-length codewords received over a data channel, and outputs the stored bit stream. The decoding unit 30 decodes contiguous variable-length codewords into original fixed-length codewords and outputs the fixed-length codewords in response to a read signal. The interfacing unit 20 interfaces the external memory buffer 10 and the decoding unit 30 and provides the decoding unit 30 with the serial bit stream output from the external memory buffer 10.

The interfacing unit 20 includes a first flip-flop 21, a second flip-flop 22, a first barrel shifter 24, an adder 26, and an accumulation register 28. The first flip-flop 21 and second flip-flop 22 temporarily store data output from the external memory buffer 10 and output the stored data. The adder 26 adds together the lengths of currently decoded codewords output from the decoding unit 30 and the lengths of the previously decoded codewords. If the sum exceeds the maximum codeword length, the adder 26 generates a carry signal. The accumulation register 28 then stores the sum of the adder 26. The first barrel shifter 24 receives data from the external memory buffer 10, the first flip-flop 21, and the second flip-flop 22, shifts the received data based on the sum of the adder 26, and outputs the shifted data to the decoding unit 30.

The decoding unit 30 includes a third flip-flop 31, a fourth flip-flop 32, a fifth flip-flop 33, a second barrel shifter 34, and a variable-length code table 35. The fourth flip-flop 32 temporarily stores data output from the first barrel shifter 24 of the interfacing unit 20. The variable-length code table 35 includes a codeword table 36, a code length table 37, and a decoded codeword table 38. The variable-length code table 35 is programmable, decodes contiguous variable-length codewords and their lengths, and outputs a serial bit stream. The fifth flip-flop 33 stores the lengths of decoded codewords. The second barrel shifter 34 shifts data output from the third flip-flop 31 and the fourth flip-flop 32, based on the lengths of decoded codewords output from the fifth flip-flop 33. Then the second barrel shifter 34 outputs the shifted data to the variable-length code table 35. The third flip-flop 31 receives the output of the second barrel shifter 34.

Hereinafter, the operation of the conventional variable-length decoder will be described.

The external memory buffer 10 stores a serial bit stream of variable-length codewords received over a data channel. The variable-length codewords are output to the decoding unit 30 through the interfacing unit 20, based on the lengths of the decoded codewords output from the fifth flip-flop 33 of the decoding unit 130. Then the decoding unit 30 decodes contiguous variable-length codewords into fixed-length codewords. For an input sequence of bits representing an unidentified variable-length codeword, the variable-length code table 35 of the decoding unit 30 outputs, a fixed-length codeword corresponding to a variable-length codeword and the length of the variable-length codeword. The variable-length code table 35 includes a table look-up memory. The output of the second barrel shifter 34 of the decoding unit 30 is provided as input for producing the next decoded codeword, using the table look-up memory of the variable-length code table 35. The second barrel shifter 34 is controlled by the lengths of decoded codewords output from the fifth flip-flop 33.

The second barrel shifter 34 receives data from the third flip-flop 31 and the fourth flip-flop 32. The third flip-flop 31 and the fourth flip-flop 32 each have bit capacity equal to the maximum codeword length. The output of the second barrel shifter 34 is connected to the table look-up memory of the variable-length code table 35. When the interfacing unit 20 provides data to the fourth flip-flop 32, the second barrel shifter 34 is connected to the third flip-flop 31. At each clock cycle, the second barrel shifter 34 provides the variable-length code table 35 with the number of bits corresponding to the maximum codeword length in a serial bit stream, which is equal to twice the maximum codeword length stored in the third flip-flop 31 and the fourth flip-flop 32.

The variable-length code table 35 outputs a codeword length and corresponding decoded codewords from the table look-up memory to the fifth flip-flop 33. The codeword length corresponds to the output of the second barrel shifter 34.

The fifth flip-flop 33 provides the second barrel shifter 34 with the lengths of previously decoded variable-length codewords, received from the variable-length code table 35. These lengths correspond to the variable-length codewords to be decoded next. In other words, the output of the second barrel shifter 34 is shifted by a number equal to the sum of lengths of the previously decoded codewords output from the fifth flip-flop 33, and then begins with the first bit of the variable-length codewords to be decoded next.

Since the bits within the third flip-flop 31 are converted at each clock cycle, the fourth flip-flop 32 is provided with data output from the interfacing unit 20 at each clock cycle. Thus, a bit stream, starting from the decoded codeword, is provided to the second barrel shifter 34.

The fourth flip-flop 32 receives the output of the first barrel shifter 24 of the interfacing unit 20.

The first barrel shifter 24 receives data from the external memory buffer 10, the first flip-flop 21, and the second flip-flop 22. The first flip-flop 21 is provided with data from the external memory buffer 10. Then the second flip-flop 22 stores and outputs data from the first flip-flop 21. The lengths of variable-length codewords stored in the first flip-flop 21 and the second flip-flop 22 are equal to the maximum codeword length.

The output of the first barrel shifter 24 is controlled by the sum of the adder 26. The sum is obtained by adding together the lengths of currently decoded codewords output from the decoding unit 30 and the lengths of previously decoded codewords. In other words, the output of the first barrel shifter 24 is shifted based on the lengths of previously decoded codewords. The output of the first barrel shifter 24 and the output of the second barrel shifter 34 of the decoding unit 30 constitute a bit stream. The lengths of the previously decoded codewords may exceed the maximum codeword length, i.e., the adder 26 generates a carry signal. Such an event indicates that all bits stored in the second flip-flop 22 are transferred to the decoding unit 30. In other words, when the carry signal is generated, the content of the first flip-flop 21 is transferred to the second flip-flop 22, and thus, the output of the external memory buffer 10 is transferred into the second flip-flop 22. At the same time, the next fixed-length data segment of bits is detected by the external memory buffer 10.

In this way, based on the lengths of previously decoded codewords, the first barrel shifter 24 shifts the data that is sequentially output from the external memory buffer 10 and outputs the shifted data to the decoding unit 30. Consequently, the decoding unit 30 decodes the variable-length codewords in the way described above.

The conventional variable-length decoder uses two barrel shifters and processes all syntaxes in hardware, i.e., a programmable logic array (PLA). Accordingly, the use of two barrel shifters instead of one barrel shifter results in a large amount of calculations and complicates the circuit configuration of the variable-length decoder.

### SUMMARY OF THE INVENTION

The present invention provides a programmable variable-length decoder, which interfaces with a central processing unit (CPU) processor, performs a partial variable-length decoding operation using the CPU processor and reduces both the amount of calculations and its circuit size by using one barrel shifter.

According to one aspect of the present invention, there is provided a programmable variable-length decoder that interfaces an external processor. The programmable variable-length decoder comprises a memory buffer, a latching unit, a multiplexing unit, a first barrel shifter, a decoding unit, and a control unit. The memory buffer stores input serial bit stream data for decoding in fixed-length data segments and outputs the stored bit stream data in response to a first control signal. The latching unit temporarily stores data output from the memory buffer and outputs the stored data in response to the first control signal. The multiplexing unit selects data from the latching unit and outputs the selected data. The first barrel shifter shifts the selected data output from the multiplexing unit by a second control signal value and outputs the shifted data. The decoding unit decodes the output of the first barrel shifter and outputs decoded codewords and a bit length of the decoded codewords. The control unit adds together bit lengths of currently decoded codewords and bit lengths of previously decoded codewords, stores a sum, generates the first control signal and a second control signal based on the sum, and outputs the first control signal and the second control signal to the latching unit and the first barrel shifter.

Preferably, the programmable variable-length decoder further comprises a processor data interfacing unit, which transmits the output of the first barrel shifter to an external processor for enabling the performance of the first barrel shifter to an external processor of variable-length decoding in the external processor. The processor data interfacing unit includes a second barrel shifter which shifts the output of the first barrel shifter by a bit length provided by the external processor and outputs the shifted data.

The latching unit comprises a first latch, a second latch, and a third latch. The first latch temporarily stores the output of the memory buffer and outputs the stored data in response to the first control signal. The second latch temporarily stores the output of the first latch and outputs the stored data in response to the first control signal. The. third latch temporarily stores the output of the second latch and outputs the stored data in response to the first control signal.

Preferably, the multiplexing unit comprises a first multiplexer and a second multiplexer. The first multiplexer selects either the output of the first latch or the output of the second latch in response to a selection control signal, and outputs the selected data as lower bits to the first barrel shifter. The second multiplexer selects either the output of the second latch or the output of the third latch in response to the selection control signal, and outputs the selected data as upper bits to the first barrel shifter.

Preferably, the decoding unit comprises a symbol decoder and a length decoder. The symbol decoder decodes the output of the first barrel shifter and converts detected variable-length codewords into fixed-length codewords. The length decoder outputs a bit length of the detected variable-length codewords to the control unit.

Preferably, the decoding unit further comprises a codeword table, including a programmable logic array, and the symbol decoder decodes the output of the first barrel shifter into codewords based on the codeword table, represents the decoded codewords as a predetermined value, and outputs the predetermined value.

Preferably, the control unit comprises a third multiplexer, an adder, an accumulation register, and a carry register. The third-multiplexer selects either the bit length of the detected variable-length codewords, output from a length decoder, or the bit length provided by the external processor. The adder adds together a selected bit length of currently decoded codewords and a bit length of previously decoded codewords. The accumulation register stores a sum of the adder, i.e., a sum of the bit lengths of previously decoded codewords and the selected bit lengths of currently decoded codewords, outputs the sum of the adder as the second control signal to the first barrel shifter, and as the bit lengths of previously decoded codewords. The carry register temporarily stores a carry signal generated during operation of the adder, and outputs the carry signal as the first control signal to the memory buffer and the latching unit.

Preferably, the memory buffer stores input bit stream data in a format of 16 bits.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram of a conventional variable-length decoder;

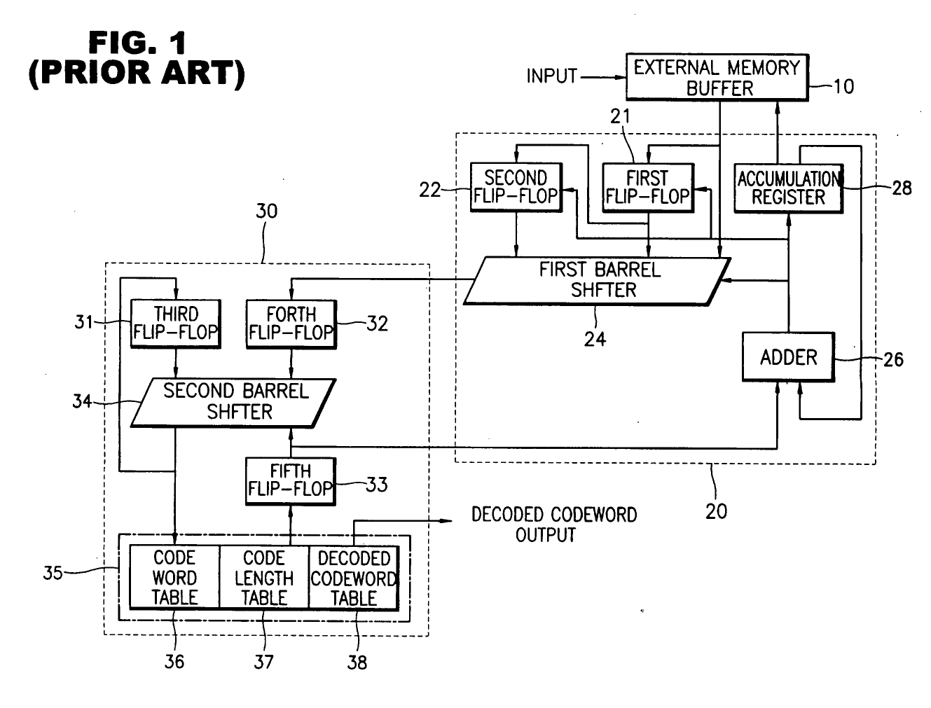

FIG. 2 is a block diagram of a programmable variable-length decoder according to the present invention;

FIG. 3 illustrates an embodiment of bit stream data stored in a memory buffer; and

FIG. 4 illustrates an embodiment of data in each unit of FIG. 2.

### DETAILED DESCRIPTION OF THE INVENTION

The present invention now will be described more fully with reference to the accompanying drawings, in which preferred embodiments of the invention are shown.

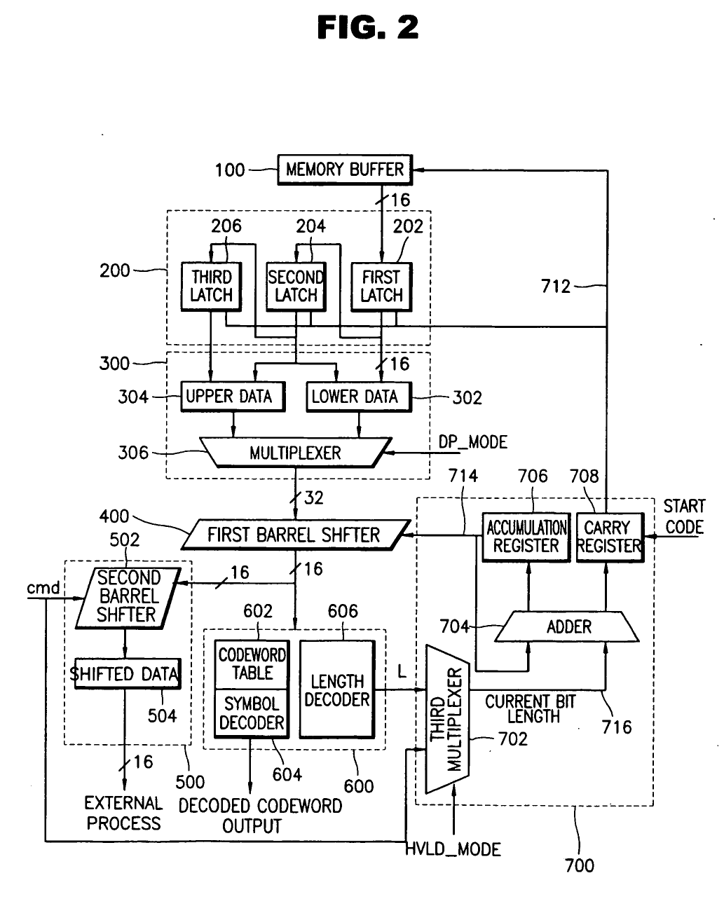

FIG. 2 is a block diagram of a programmable variable-length decoder according to the present invention.

Referring to FIG. 2, the programmable variable-length decoder includes a memory buffer 100, a latching unit 200, a multiplexing unit 300, a first barrel shifter 400, a decoding unit 600, and a control unit 700. The programmable variable-length decoder may optionally include a processor data interfacing unit 500.

The memory buffer 100 stores an input bit stream of a predetermined number of bits, e.g., 16 bits, and outputs the stored bit stream in response to a first control signal output from the control unit 700.

The latching unit 200 includes a first latch 202, a second latch 204, and a third latch 206. The first latch 202 temporarily stores data output from the memory buffer 100 and outputs the stored data in response to the first control signal from the control unit 700. The second latch 204 temporarily stores data output from the first latch 202 and outputs the stored data in response to the first control signal. The third latch 206 temporarily stores data output from the second latch 204 and outputs the stored data in response to the first control signal. In other words, in response to the first control signal output from the control unit 700, data output from the second latch 204 is transferred to the third latch 206, data output from the first latch 202 is transferred to the second latch 204, and data output from the memory buffer 100 is transferred to the first latch 202.

The multiplexing unit 300 selects data from the latching unit 200 according to data partition mode DP_MODE and outputs the selected data to the first barrel shifter 400. Namely, the outputs of the first latch 202 and the second latch 204 constitute lower data 302, and the outputs of the second latch 204 and the third latch 206 constitute upper data 304. When data partition mode DP_MODE is ‘0’, data output from the third latch 206 constitute the upper data 304 and data output from the second latch 204 constitute the lower data 302. When data partition mode DP_MODE is ‘1’, data output from the second latch 204 constitute the upper data 304 and data output from the first latch 202 constitute the lower data 302.

The multiplexer 306 includes a first multiplexer (not shown) and a second multiplexer (not shown). The first multiplexer selects either data output from the first latch 202 or data output from the second latch 204, according to data partition mode DP_MODE, and outputs lower data 302. The second multiplexer selects either data output from the second latch 204 or output from the third latch 206, according to data partition mode DP_MODE, and outputs upper data 304. In other words, when data partition mode DP_MODE is ‘0’, the first multiplexer selects data output from the second latch 204 and outputs the selected data as the lower 16 bits of input to the first barrel shifter 400, and the second multiplexer selects data output from the third latch 206 and outputs the selected data as the upper 16 bits of input to the first barrel shifter 400. When data partition mode DP_MODE is ‘1’, the first multiplexer selects data output from the first latch 202 and outputs the selected data as the lower 16 bits of input to the first barrel shifter 400, and the second multiplexer selects data output from the second latch 204 and outputs the selected data as the upper 16 bits of input to the first barrel shifter 400.

The first barrel shifter 400 shifts the data output from the multiplexing unit 300 by the value of the second control signal that is output from the control unit 700, and outputs the shifted data to the decoding unit 600.

The processor data interfacing unit 500 provides the output of the first barrel shifter 400 to an external processor, e.g., a central processing unit (CPU) processor, for VLC decoding. The processor data interfacing unit 500 includes a second barrel shifter 502 and shifted data 504 that transfers shifted data into the external processor. The second barrel shifter 502 shifts the output of the first barrel shifter 400 by a bit length ‘cmd’ provided by the external processor and outputs shifted data 504 to the external processor.

By including the processor data interfacing unit 500, the external processor can process header syntaxes of the variable-length decoder, and the hardware of the variable-length decoder can process the large amount of calculations. The variable-length decoder of the present invention configures the external processor in such a way that the external processor performs header syntax parsing. In addition, the variable-length decoder of the present invention includes only one barrel shifter, so that the amount of calculations and the overall size of the variable-length decoder can be reduced.

The decoding unit 600 includes a codeword table 602, a symbol decoder 604, and a length decoder 606. The decoding unit 600 decodes the output of the first barrel shifter 400, and outputs decoded codewords and a bit length L. The symbol decoder 604 decodes the output of the first barrel shifter 400 and converts detected variable-length codewords into fixed-length codewords. In other words, the symbol decoder 604 decodes the output of the first barrel shifter 400 into codewords based on the codeword table 602, represents the decoded codewords as a predetermined value, and outputs the predetermined value. The codeword table 602 may take the form of a programmable logic array (PLA). The length decoder 606 outputs the bit length L, corresponding to the detected variable-length codewords, to the control unit 700.

The control unit 700 includes a third multiplexer 702, an adder 704, an accumulation register 706, and a carry register 708. The adder 704 adds together the bit length L of currently decoded codewords and a previously stored bit length 714, and stores the sum of the adder 704. Based on the sum of the adder 704, the control unit 700 generates a first control signal 712 and a second control signal 714 and outputs them to the memory buffer 100, the latching unit 200, and the first barrel shifter 400.

The third multiplexer 702 selects either the bit length L output from the length decoder 606 or the bit length ‘cmd’ provided by the external processor. The external processor provides the bit length ‘cmd’ when performing header parsing. The third multiplexer 702 outputs a current bit length 716.

The adder 704 adds together the current bit length 716 and a previously stored bit length 714.

The accumulation register 706 stores the sum of the adder 704, i.e., the bit lengths of previously decoded codewords. The accumulation register 706 outputs the sum of the adder 704 as the second control signal 714 to the first barrel shifter 400 and provides the sum of the adder 704 as the previously stored bit length 714 to the adder 704.

The carry register 708 temporarily stores the carry signal generated during the operation of the adder 704, and outputs the carry signal as the first control signal 712 to the memory buffer 100 and the latching unit 200.

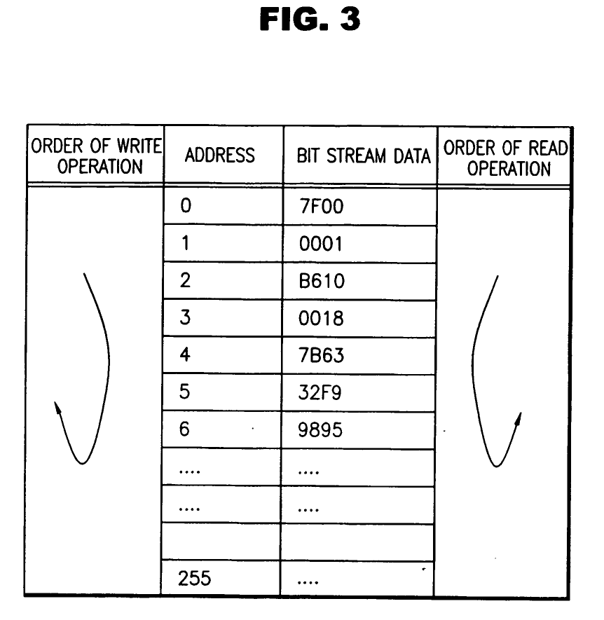

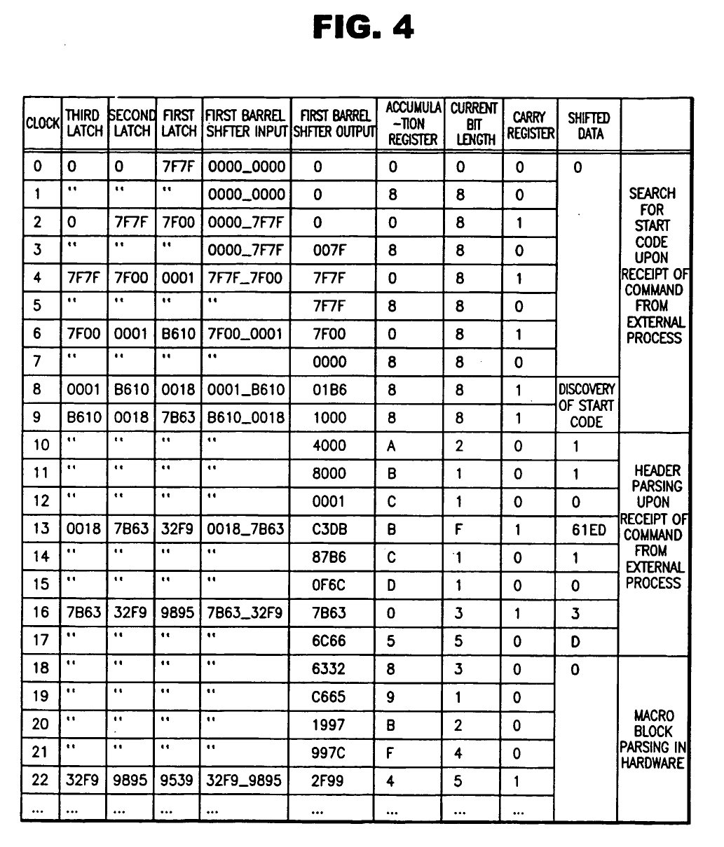

In the present invention, 16-bit data is stored or output, but the number of bits is not limited to 16. Hereinafter, the operation of the variable-length decoder will be described with reference to FIGS. 3 and 4.

FIG. 3 illustrates an embodiment of the bit stream data stored in the memory buffer 100. FIG. 4 illustrates an embodiment of data in each unit of FIG. 2. FIG. 3 illustrates the configuration of bit stream data in the memory buffer 100 and the address of the bit stream. When the bit stream shown in FIG. 3 is input to the memory buffer 100, the first latch 202 is initialized to “7F7F”, as shown in FIG. 4.

At the first clock cycle, the third multiplexer 702 receives a command from the external processor to search for a start code and outputs the current bit length as “8” until the start code is found.

At the second clock cycle, the carry signal “1” is generated. Then bit stream data “7F00”, corresponding to address “0”, is read from the memory buffer 100 and stored in the first latch 202. At the same time, data stored in the first latch 202, i.e., “7F7F”, is transmitted to the second latch 204, and data stored in the second latch 204, i.e., “0000”, is transmitted to the third latch 206. In FIG. 4, data partition mode DP_MODE is set to “0”. In this case, the output of the multiplexing unit 300 consists of the output of the third latch 206, which constitutes the upper data 304, and the output of the second latch 204, which constitutes the lower data 302. The output of the multiplexing unit 300, “0000_{—}7F7F”, is input to the first barrel shifter 400. Since the accumulation register 706 outputs “0”, the first barrel shifter 400 shifts “0000_{—}7F7F” by “0” and outputs “0000”.

At the third clock cycle, since the accumulation register 706 outputs “8”, the first barrel shifter 400 shifts “0000_{—}7F7F” by “8” and outputs “007F”.

At the fourth clock cycle, the carry signal “1” is output. Then bit stream data “0001”, corresponding to address “1”, is read from the memory buffer 100 and stored in the first latch 202. At the same time, data stored in the first latch 202, i.e., “7F00”, is transmitted to the second latch 204, and data stored in the second latch 204, i.e., “7F7F”, is transmitted to the third latch 206. The first barrel shifter 400 receives “7F7F_{—}7F00”. Since the accumulation register 706 outputs “0”, the first barrel shifter 400 shifts “7F7F_{—}7F00” by “0” and outputs “7F7F”.

At the sixth clock cycle, the carry signal “1” is output. Then bit stream data “B610” corresponding to address “2” is read from the memory buffer 100 and stored in the first latch 202. At the same time, data stored in the first latch 202, i.e., “0001”, is transmitted to the second latch 204, and data stored in the second latch 204, i.e., “7F00”, is transmitted to the third latch 206. The first barrel shifter 400 receives “7F00_{—}0001”. Since the accumulation register 706 outputs “0”, the first barrel shifter 400 shifts “7F00_{—}0001” by “0” and outputs “7F00”. At the eighth clock cycle, the carry signal “1” is output. Then bit stream data “0018”, corresponding to address “3”, is read from the memory buffer 100 and stored in the first latch 202. At the same time, data stored in the first latch 202, i.e., “B610”, is transmitted to the second latch 204, and data stored in the second latch 204, i.e., “0001”, is transmitted to the third latch 206. The first barrel shifter 400 receives “0001_B610”. Since the accumulation register 706 outputs “8” (if the start code has been found, the accumulation register 706 holds “8”), the first barrel shifter 400 shifts “0001_B610” by “8” and outputs “01B6”. The external processor is notified, of discovery of the start code. Thereafter, the bit stream is obtained based on the current bit length 716 and provided to the processor data interfacing unit 500 during the tenth through seventh clock cycles.

At the tenth clock cycle, the first barrel shifter 400 outputs “4000”, and the second barrel shifter 502 shifts “4000” by the bit length “cmd” which is equal to “2”. The second barrel shifter 502 outputs “1” as the shifted data 504. The external processor receives the shifted data 504 and uses it for header parsing.

At the eleventh clock cycle, when the external processor outputs “1” as the bit length “cmd” to the second barrel shifter 502, the current bit length 716 is “1”. Thus, the first barrel shifter 400 outputs “8000”, and the second barrel shifter 502. receives “8000”, shifts “8000” by “1”, and outputs “1” as the shifted data 504. In this way, the external processor performs variable-length decoding.

The PLA of the decoding unit 600 forms decoded codewords. The variable-length decoder processes the code lengths of the decoded codewords in the decoding unit 600.

At the eighteenth clock cycle, since the current bit length is “3”, the accumulation register 706 outputs “8”. Thus, the first barrel shifter 400 shifts the received “7B63_{—}32F9” by “8” and outputs “6332”. The decoding unit 600 decodes “6332” and notifies the control unit 700 that a 1-bit codeword length is used at the nineteenth clock cycle.

In the present invention, a portion of header parsing is implemented as a program and decoding for units smaller than a macro block is performed in hardware.

According to the programmable variable-length decoder of the present invention, it is possible to reduce the amount of calculation and the overall size of the variable-length decoder, by using only one barrel shifter. Since the variable-length decoder interfaces with the external processor, the external processor can perform a portion of variable-length decoding. In particular, it is possible to separately perform header parsing for MPEG syntaxes and VLC parsing for macro blocks. Thus, the variable-length decoder can process header syntaxes by interfacing with the external processor.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A programmable variable-length decoder that interfaces an external processor, the programmable variable-length decoder comprising:
a memory buffer, which stores input serial bit stream data for decoding in fixed-length data segments and outputs the stored bit stream data in response to a first control signal;
a latching unit, which temporarily stores data output from the memory buffer and outputs the stored data in- response to the first control signal;
a multiplexing unit, which selects data from the latching unit and outputs the selected data;
a first barrel shifter, which shifts the selected data output from the multiplexing unit by a second control signal value and outputs the shifted data;
a decoding unit, which decodes the output of the first barrel shifter, and outputs decoded codewords and a bit length of the decoded codewords;
a control unit, which adds together bit lengths of currently decoded codewords and bit lengths of previously decoded codewords, stores a sum, generates the first control signal and a second control signal based on the sum, and outputs the first control signal and the second control signal to the latching unit and the first barrel shifter; and
a processor data interfacing unit, which transmits the output of the first barrel shifter to an external processor for enabling the performance of the first barrel shifter to an external processor of variable-length decoding in the external processor,
wherein the processor data interfacing unit includes a second barrel shifter which shifts the output of the first barrel shifter by a bit length provided by the external processor and outputs the shifted data.

2. The programmable variable-length decoder of claim 1, wherein the latching unit comprises:
a first latch, which temporarily stores the output of the memory buffer and outputs the stored data in response to the first control signal;
a second latch, which temporarily stores the output of the first latch and outputs the stored data in response to the first control signal; and
a third latch, which temporarily stores the output of the second latch and outputs the stored data in response to the first control signal.

3. The programmable variable-length decoder of claim 2, wherein the multiplexing unit comprises:
a first multiplexer, which selects either the output of the first latch or the output of the second latch in response to a selection control signal, and outputs the selected data as lower bits to the first barrel shifter; and
a second multiplexer, which selects either the output of the second latch or the output of the third latch in response to the selection control signal, and outputs the selected data as upper bits to the first barrel shifter.

4. The programmable variable-length decoder of claim 1, wherein the decoding unit comprises:
a symbol decoder, which decodes the output of the first barrel shifter and converts detected variable-length codewords into fixed-length codewords; and
a length decoder, which outputs a bit length of the detected variable-length codewords to the control unit.

5. The programmable variable-length decoder of claim 4, wherein the decoding unit further comprises a codeword table, including a programmable logic array, and the symbol decoder decodes the output of the first barrel shifter into codewords based on the codeword table, represents the decoded codewords as a predetermined value, and outputs the predetermined value.

6. The programmable variable-length decoder of claim 4, wherein the control unit comprises:
a third multiplexer, which selects either the bit length of the detected variable-length codewords, output from a length decoder, or the bit length provided by the external processor;
an adder, which adds together a selected bit length of currently decoded codewords and a bit length of previously decoded codewords;
an accumulation register, which stores a sum of the adder, i.e., a sum of the bit lengths of previously decoded codewords and the selected bit lengths of currently decoded codewords, outputs the sum of the adder as the second control signal to the first barrel shifter, and as the bit lengths of previously decoded codewords; and
a carry register, which temporarily stores a carry signal generated during operation of the adder, and outputs the carry signal as the first control signal to the memory buffer and the latching unit.

7. The programmable variable-length decoder of claim 1, wherein the memory buffer stores input bit stream data in a format of 16 bits.
